(19) United States
(12) Patent Application Publication
(10) Pub. No.: US 2008/0217646 A1
(43) Pub. Date: Sep. 11, 2008

(54) Nitride semiconductor light emitting device

(75) Inventor: Satoshi Komada, Mihara-shi (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/073,215

(22) Filed: Mar. 3, 2008

(30) Foreign Application Priority Data
Mar. 8, 2007 (JP) 2007-058804 (P)

(51) Int. Cl. H01L 33/00

(52) U.S. Cl. 257/101; 257/102; 257/E33.03

(57) ABSTRACT

The present invention presents a nitride semiconductor light emitting device including a substrate, a first n-type nitride semiconductor layer, a light emitting layer, a p-type nitride semiconductor layer, a p-type nitride semiconductor tunnel junction layer, an n-type nitride semiconductor tunnel junction layer, and a second n-type semiconductor layer, in which the p-type and n-type nitride semiconductor tunnel junction layers form a tunnel junction, at least one of the p-type and n-type nitride semiconductor tunnel junction layers contains In, at least one of In-containing layers contacts with a layer having a larger band gap than the In-containing layer, and at least one of shortest distances between an interface of the In-containing layer and the layer having a larger band gap and an interface of the p-type and n-type nitride semiconductor tunnel junction layers is less than 40 nm.

This nonprovisional application is based on Japanese Patent Application No. 2007-058804 filed with the Japan Patent Office on Mar. 8, 2007, the entire contents of which are hereby incorporated by reference.

### BACKGROUND OF THE INVENTION

1. Field of the Invention

The present invention relates to a nitride semiconductor light emitting device, and particularly relates to a nitride semiconductor light emitting device having a tunnel junction.

2. Description of the Background Art

Conventionally, in a nitride semiconductor light emitting diode device in which a p-type nitride semiconductor layer side is a light outgoing side, a p-side electrode formed on the p-type nitride semiconductor layer is desired to satisfy the following three conditions.

First, a first condition is that transmittance to light emitted from the nitride semiconductor light emitting diode device is high. Next, a second condition is to have a specific resistance and thickness capable of sufficiently diffusing injecting current into the face of the light emitting layer. Finally, a third condition is that contact resistance with the p-type nitride semiconductor layer is low.

A semi-transparent metal electrode made of a metal film having a thickness of a few to about 10 nm, such as palladium and nickel, is conventionally formed on the entire face of the p-type nitride semiconductor layer as the p-side electrode formed on the p-type nitride semiconductor layer of the nitride semiconductor light emitting diode device in which the side of the p-type nitride semiconductor layer is a light outgoing side. However, such a semi-transparent metal electrode has a problem that since the transmittance to light emitted from the nitride semiconductor light emitting diode device is as low as about 50%, light outgoing efficiency lowers and therefore it is difficult to obtain a high-brightness nitride semiconductor light emitting diode device.

In order to solve the problem, by forming a transparent conductive film made of ITO (Indium Tin Oxide) on the entire face of the p-type nitride semiconductor layer instead of the semi-transparent metal electrode made of a film of metal, such as palladium and nickel, a high-brightness nitride semiconductor light emitting diode device having an improved light outgoing efficiency is manufactured. In such a nitride semiconductor light emitting diode device in which the transparent conductive film is formed, the contact resistance of the transparent conductive film with the p-type nitride semiconductor layer that has been a worry is improved by a heat treatment, and the like.

Japanese Patent Laying-Open No. 2002-319703 discloses a nitride semiconductor light emitting diode device including a group III nitride semiconductor layered structure having at least a first n-type group III nitride semiconductor layered structure, a p-type group III nitride semiconductor layered structure, and a second n-type group III nitride semiconductor layered structure, formed on a substrate, in which a negative electrode is provided in an n-type group III nitride semiconductor layer in the first n-type group III nitride semiconductor layered structure, a positive electrode is provided in an n-type group III nitride semiconductor layer in the second n-type group III nitride semiconductor layered structure, and a tunnel junction is formed with the n-type group III nitride semiconductor layer in the second n-type group III nitride semiconductor layered structure and the p-type group III nitride semiconductor layer in the p-type group III nitride semiconductor layered structure.

In the nitride semiconductor light emitting diode device disclosed in Japanese Patent Laying-Open No. 2002-319703, since the positive electrode is formed in the n-type group III nitride semiconductor layer in the second n-type group III nitride semiconductor layered structure, and the n-type group III nitride semiconductor is capable of increasing a carrier concentration easily as compared with the p-type group III nitride semiconductor, the contact resistance can be reduced as compared with the conventional structure in which the positive electrode is formed in the p-type group III nitride semiconductor layer, to achieve low driving voltage and high output drive. Further, since heat generation at the positive electrode which is one cause of breakdown of the nitride semiconductor light emitting diode device can be reduced, it is said that reliability can be improved.

### SUMMARY OF THE INVENTION

However, there is a problem that optical characteristics of the transparent conductive film made of ITO change irreversibly at a high temperature to decrease transmittance of visible light. In the case of using the transparent conductive film made of ITO, there is also a problem that a process temperature range after the formation of the transparent conductive film made of ITO is limited in order to prevent the transmittance of visible light from decreasing. In addition, there is a problem that the transparent conductive film made of ITO deteriorates due to driving of high current density and blackens.

Further, in the nitride semiconductor light emitting diode device described in Example of Japanese Patent Laying-Open No. 2002-319703, a tunnel junction is formed with a p-type InGaN layer and an n-type InGaN layer which have the In (indium) composition ratio of the same level as that of a light emitting layer, and both the layer thicknesses are 50 nm.

As described in Example of Japanese Patent Laying-Open No. 2002-319703, in order to sufficiently supply In as a solid phase, it is necessary to lower a growth temperature to about 800° C. However, since it is difficult to obtain the p-type InGaN layer having a high carrier concentration of 1×10¹⁹/cm³ or more at a low temperature, voltage loss at a tunnel junction part cannot be decreased, and as a result, there is a problem that the driving voltage becomes high.

Therefore, an object of the present invention is to provide a nitride semiconductor light emitting device capable of decreasing driving voltage.

The present invention relates to a nitride semiconductor light emitting device including a substrate, a first n-type nitride semiconductor layer, a light emitting layer, a p-type nitride semiconductor layer, a p-type nitride semiconductor tunnel junction layer, an n-type nitride semiconductor tunnel junction layer, and a second n-type semiconductor layer, which are formed on the substrate, in which the p-type nitride semiconductor tunnel junction layer and the n-type nitride semiconductor tunnel junction layer form a tunnel junction, at least one of the p-type nitride semiconductor tunnel junction layer and the n-type nitride semiconductor tunnel junction layer contains In, at least one of In-containing layers, which are at least one of the p-type nitride semiconductor tunnel junction layer and the n-type nitride semiconductor tunnel junction layer contacts with a layer having a larger band gap than the In-containing layer, and at least one of shortest distances between an interface of the In-containing layer and the layer having a large band gap and an interface of the p-type nitride semiconductor tunnel junction layer and the n-type nitride semiconductor tunnel junction layer is less than 40 nm.

In the nitride semiconductor light emitting device of the present invention, the ratio of the number of In atoms to the total number of Al, Ga, and In atoms in the In-containing layer is preferably larger than 0.1.

In the nitride semiconductor light emitting device of the present invention, it is preferable that the n-type nitride semiconductor tunnel junction layer is an In-containing layer and the concentration of an n-type dopant in the n-type nitride semiconductor tunnel junction layer is less than 5×10¹⁹/cm³.

In the nitride semiconductor light emitting device of the present invention, the n-type dopant is preferably at least one kind selected from the group consisting of Si, Ge, and O.

In the nitride semiconductor light emitting device of the present invention, the concentration of a p-type dopant in the p-type nitride semiconductor tunnel junction layer is preferably 2×10¹⁹/cm³ or more.

In the present invention, “the concentration of the p-type dopant” indicates the atomic concentration of the p-type dopant contained in the nitride semiconductor, “the concentration of the n-type dopant” indicates the atomic concentration of the n-type dopant contained in the nitride semiconductor, and each concentration can be calculated quantitatively with a method such as SIMS (Secondary Ion Mass Spectrometry).

Further, in the present description, Al represents aluminum, Ga represents gallium, and In represents indium.

According to the present invention, a nitride semiconductor light emitting device capable of decreasing driving voltage can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of one preferable example of a nitride semiconductor light emitting diode device showing one example of the nitride semiconductor light emitting device in the present invention.

FIG. 2 is a schematic cross-sectional view of another preferable example of the nitride semiconductor light emitting diode device showing one example of the nitride semiconductor light emitting device in the present invention.

FIG. 3 is a view showing a relationship between the thickness (nm) of a p-type tunnel junction layer and the driving voltage (V) of a nitride semiconductor light emitting diode device in Example 1.

FIG. 4 is a view showing a relationship between the thickness (nm) of a p-type tunnel junction layer and the driving voltage (V) of a nitride semiconductor light emitting diode device in Example 3.

FIG. 5 is a schematic cross-sectional view of another preferable example of the nitride semiconductor light emitting diode device showing one example of the nitride semiconductor light emitting device in the present invention.

### DESCRIPTION OF THE PREFERRED EMBODIMENTS

Hereinafter, embodiments of the present invention will be described. Moreover, in the drawings of the present invention, the same reference numerals represent the same parts or corresponding parts.

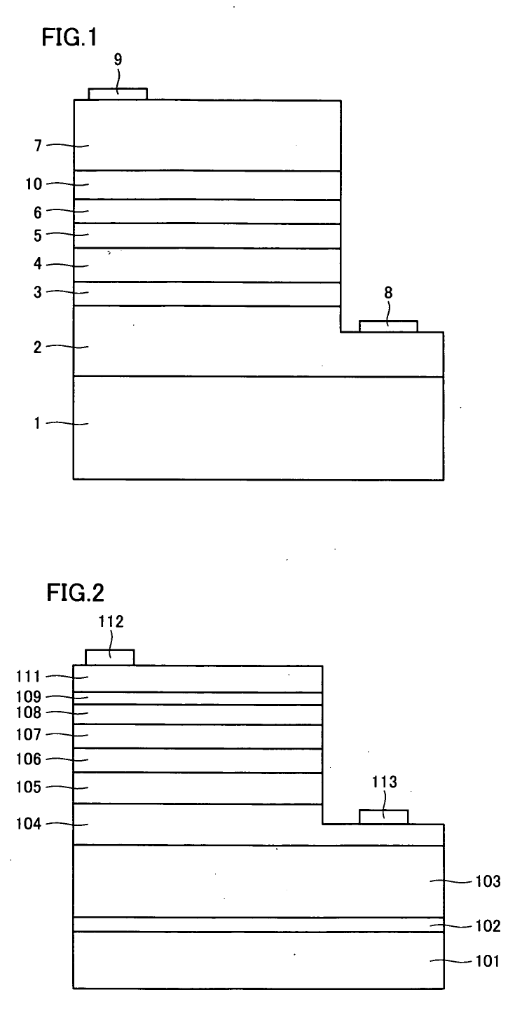

FIG. 1 is a schematic cross-sectional view of one preferable example of a nitride semiconductor light emitting diode device showing one example of the nitride semiconductor light emitting device in the present invention. The nitride semiconductor light emitting diode device shown in FIG. 1 has a substrate 1, a first n-type nitride semiconductor layer 2, a light emitting layer 3, a p-type nitride semiconductor layer 4, a p-type nitride semiconductor tunnel junction layer 5, an n-type nitride semiconductor tunnel junction layer 6, an n-type nitride semiconductor evaporation suppressing layer 10, and a second n-type nitride semiconductor layer 7, which are layered in turn on substrate 1, and has a configuration in which an n-side electrode 8 is formed on first n-type nitride semiconductor layer 2, and a p-side electrode 9 is formed on second n-type nitride semiconductor layer 7.

In the nitride semiconductor light emitting device of such a configuration, it is required that the contact resistance can be reduced as compared with a conventional structure in which a positive electrode is formed on a conventional p-type nitride semiconductor layer and the driving voltage can be made low, while the voltage loss at a tunnel junction part which is a junction part of p-type nitride semiconductor tunnel junction layer 5 and n-type nitride semiconductor tunnel junction layer 6 can be reduced more.

A tunneling probability Tt at this tunnel junction part is generally represented by the following equation (1):

Tt=exp((−8π(2me)^{1/2}Eg^{3/2})/(3qhε)) (1)

wherein Tt represents a tunneling probability, me represents an effective mass of a conductive electron, Eg represents an energy gap, q represents a charge of an electron, h represents a Planck's constant, and ε represents an electric field in the tunnel junction part.

In order to decrease the driving voltage of the nitride semiconductor light emitting device, it is desired to increase this tunneling probability Tt. From equation (1) described above, increase in electronic field ε in the tunnel junction part is considered as a method of increasing a tunneling probability Tt.

As a method of increasing electronic field ε in the tunnel junction part, it is preferable to increase the effective ionization impurity concentrations of both p-type nitride semiconductor tunnel junction layer 5 and n-type nitride semiconductor tunnel junction layer 6 that form the tunnel junction high. Examples of the method of increasing the effective ionization impurity concentration include a method of utilizing two-dimensional electron gas generated at the interface where layers having a different band gap are layered.

That is, since the effective ionization impurity concentration of p-type nitride semiconductor tunnel junction layer 5 and/or n-type nitride semiconductor tunnel junction layer 6 that form the tunnel junction can be increased by positioning the generation point of the two-dimensional electron gas near the interface of p-type nitride semiconductor tunnel junction layer 5 and n-type nitride semiconductor tunnel junction layer 6, electronic field ε in the tunnel junction part can be increased. Since a narrower depletion layer can be formed by increasing electronic field ε in the tunnel junction part, the tunneling probability improves.

Therefore, the present inventors have made investigations, and as a result the inventors have found that in the case that both or any one of p-type nitride semiconductor tunnel junction layer 5 and n-type nitride semiconductor tunnel junction layer 6 contains In, and at least one of In-containing layers which are at least one of p-type nitride semiconductor tunnel junction layer 5 and n-type nitride semiconductor tunnel junction layer 6 contacts to a layer having a larger band gap than the In-containing layer, the driving voltage of the nitride semiconductor light emitting device including a tunnel junction part can be decreased even when the ionization impurity concentration of p-type nitride semiconductor tunnel junction layer 5 is low by making at least one of the shortest distances between the interface of the In-containing layer and the layer having a larger band gap and the interface of p-type nitride semiconductor tunnel junction layer 5 and n-type nitride semiconductor tunnel junction layer 6 less than 40 nm, preferably 20 nm or less, and more preferably 15 nm or less. The present invention has been completed.

From the viewpoint of decreasing the driving voltage and at the same time decreasing the absorption amount of the light from light emitting layer 3, the shorter the above-described shortest distance is, the more preferable it is. However, in the case that it becomes too short, when the In contain in the In-containing layer (the ratio of the number of In atoms to the total number of Al, Ga, and In atoms in the In-containing layer) becomes low, a depletion layer reaches to a part where the carrier concentration on the side of the layer having a large band gap in the In-containing layer is low. As a result, there is a fear that the tunnel probability becomes small.

Therefore, from the above-described viewpoint, the above-described shortest distance is preferably larger than 2 nm. In this case, a tendency to decrease the tunnel probability at the tunnel junction part of p-type nitride semiconductor tunnel junction layer 5 and n-type nitride semiconductor tunnel junction layer 6 can be reduced.

Further, from the above-described viewpoint, the In contain in the In-containing layer (the ratio of the number of In atoms to the total number of Al, Ga, and In atoms in the In-containing layer) is preferably larger than 0.1, and the upper limit may be 1.

In the above description, a silicon substrate, a silicon carbide substrate, a zinc oxide substrate, or the like can be used as substrate 1, for example.

In the above description, a nitride semiconductor crystal in which n dopants are doped can be used as first n-type nitride semiconductor layer 2 for example.

In the above description, a nitride semiconductor crystal having a single quantum well (SQW) structure or a multiplex quantum well (MQW) structure can be grown as light emitting layer 3, for example. In particular, one having a multiplex quantum well structure containing a nitride semiconductor crystal represented by a composition formula of AlₐIn_{b}Ga_{1-(a+b)}N (0≦a≦1, 0b≦1, 0≦1−(a+b)≦1) is preferably used. Moreover, in the above-described composition formula, a represents the composition ratio of Al, b represents the composition ratio of In, and 1−(a+b) represents the composition ratio of Ga.

In the above description, a nitride semiconductor crystal in which p-type dopants are doped is used as p-type nitride semiconductor layer 4 for example. In particular, a nitride semiconductor crystal in which the p-type GaN layer is grown on a p-type cladding layer containing Al can be used.

Further, in the above description, a material in which p-type dopants are doped in a nitride semiconductor crystal represented by a composition formula of Alₓ₁In_{y1}Ga_{1-(x1+y1)}N (0≦x1≦1, 0≦y1≦1, 0≦1−(x1+y1)≦1) can be used as p-type nitride semiconductor tunnel junction layer 5 for example. Moreover, in the above-described composition formula, x1 represents the composition ratio of Al, y1 represents the composition ratio of In, and 1−(x1+y1) represents the composition ratio of Ga.

Further, the concentration of the p-type dopant in p-type nitride semiconductor tunnel junction layer 5 is preferably 2×10¹⁹/cm³ or more. In this case, the tendency of the driving voltage of the nitride semiconductor light emitting device in the present invention decreasing becomes large.

In the above description, a material in which p-type dopants are doped in a nitride semiconductor crystal represented by a composition formula of Alₓ₂In_{y2}Ga_{1-(x2+y2)}N (0≦x2≦1, 0≦y2≦1, 0≦1−(x2+y2)≦1) can be used as n-type nitride semiconductor tunnel junction layer 6 for example. Moreover, in the above-described composition formula, x2 represents the composition ratio of Al, y2 represents the composition ratio of In, and 1−(x2+y2) represents the composition ratio of Ga.

In the case that n-type nitride semiconductor tunnel junction layer 6 is a In-containing layer, the concentration of the n-type dopant in n-type nitride semiconductor tunnel junction layer 6 is preferably less than 5×10¹⁹/cm³. In this case, a tendency to decrease the driving voltage of the nitride semiconductor light emitting device in the present invention becomes large.

In the case that p-type nitride semiconductor tunnel junction layer 5 is made of InGaN (indium gallium nitride), (i) n-type nitride semiconductor tunnel junction layer 6 is preferably made of GaN (gallium nitride), (ii) both p-type nitride semiconductor tunnel junction layer 5 and n-type nitride semiconductor tunnel junction layer 6 is preferably made of InGaN, and (iii) in the case that p-type nitride semiconductor tunnel junction layer 5 consists of GaN, n-type nitride semiconductor tunnel junction layer 6 is preferably made of InGaN. Further, p-type nitride semiconductor tunnel junction layer 5 and n-type nitride semiconductor tunnel junction layer 6 may be made of InGaN having different In content ratios from each other. In addition, GaN may be AlGaN in each case of the above-described (i) to (iii).

Moreover, there is a necessity that at least one of p-type nitride semiconductor tunnel junction layer 5 and n-type nitride semiconductor tunnel junction layer 6 is a In-containing layer in the present invention.

Further, in the case that p-type nitride semiconductor tunnel junction layer 5 and/or n-type nitride semiconductor tunnel junction layer 6 contains In, evaporation of In from these layers can be suppressed by forming n-type nitride semiconductor evaporation suppressing layer 10.

A layer doped with n-type dopants in a nitride semiconductor crystal represented by a composition formula of Al_{c}In_{d}Ga_{1-(c+d)}N (0≦c≦1, 0≦d≦1, 0≦1−(c+d)≦1) can be used as n-type nitride semiconductor evaporation suppressing layer 10. In particular, n-type GaN is preferably used. Moreover, in the above-described composition formula, c represents the composition ratio of Al, d represents the composition ratio of In, and 1−(c+d) represents the composition ratio of Ga. Further, n-type nitride semiconductor evaporation suppressing layer 10 is preferably grown at a temperature of the same level as that of p-type nitride semiconductor tunnel junction layer 5 and/or n-type nitride semiconductor tunnel junction layer 6.

Current injected from p-side electrode 9 formed on second n-type nitride semiconductor layer 7 can be diffused by forming second n-type nitride semiconductor layer 7.

A nitride semiconductor crystal doped with n-type dopants can be used as second n-type nitride semiconductor layer 7 for example. In particular, a layer having a low specific resistance is preferable, and particularly, the carrier concentration of the layer is preferably 1×10¹⁸/cm³ or more. Further, the band gap of second n-type nitride semiconductor layer 7 is preferably larger than the band gap of light emitting layer 3 in order to secure a high light outgoing effectively.

N-side electrode 8 formed on first n-type nitride semiconductor layer 2 and p-side electrode 9 formed on second n-type nitride semiconductor layer 7 are preferably formed so as to have an ohmic contact using at least one kind of metal selected from the group consisting of Ti (titanium), Hf (hafnium), and Al (aluminum), for example.

Here, a part of the surface of first n-type nitride semiconductor layer 2 is exposed by etching a wafer after the growth of the above-described second n-type nitride semiconductor layer 7 from the side of second n-type nitride semiconductor layer 7, and n-side electrode 8 can be formed on the exposed surface.

Further, a nitride semiconductor light emitting diode device with a top-and-bottom electrode structure can be made by making the side of first n-type nitride semiconductor layer 2 the light outgoing side and the side of second n-type nitride semiconductor layer 7 the supporting substrate side by pasting the second n-type nitride semiconductor layer 7 side in a wafer after the growth of second n-type nitride semiconductor layer 7 to a conductive supporting substrate prepared separately, and by forming at least one kind of metal with a high reflectivity selected from the group consisting of Al, Pt, and Ag on the supporting substrate side.

Because the carrier concentration of second n-type nitride semiconductor layer 7 can be made higher than that of the conventional p-type nitride semiconductor layer according to the nitride semiconductor light emitting diode device with such a top-and-bottom electrode structure, the ohmic characteristic due to tunneling of the carrier can be easily obtained independent of the work function of the metal, and a metal with high reflectance described above can be formed on second n-type nitride semiconductor layer 7. Therefore, the light outgoing efficiency tends to be improved.

Moreover, in the present invention, at least one kind selected from the group consisting of Si (silicon), Ge (germanium), and O (oxygen) is preferably doped as the n-type dopant for example.

Further, in the present invention, Mg (magnesium) and/or Zn (zinc), etc. can be doped as the p-type dopant for example.

### EXAMPLES

### Example 1

In Example 1, the nitride semiconductor light emitting diode device having a configuration shown in the schematic cross-sectional view of FIG. 2 was manufactured.

First, a sapphire substrate 101 was set in a reaction furnace of a MOCVD (Metal Organic Chemical Vapor Deposition) apparatus. Then, the temperature of sapphire substrate 101 was raised to 1050° C. while hydrogen flowed in the reaction furnace, to perform cleaning of the surface of sapphire substrate 101 (C face).

Next, the temperature of sapphire substrate 101 was lowered to 510° C. and hydrogen as carrier gas and ammonia and TMG (trimethyl gallium) as raw material gas flowed in the reaction furnace, to grow a GaN buffer layer 102 on the surface of sapphire substrate 101 (C face) to a thickness of about 20 nm with a MOCVD method.

The temperature of sapphire substrate 101 was raised to 1050° C. and hydrogen as carrier gas, ammonia and TMG (trimethyl gallium) as raw material gas, and silane as impurity gas flowed in the reaction furnace, to grow an n-type GaN under-layer 103 (carrier concentration: 1×10¹⁸/cm³) doped with Si on GaN buffer layer 102 to a thickness of 6 μm with a MOCVD method.

Subsequently, an n-type GaN contact layer 104 was grown on n-type GaN under-layer 103 to a thickness of 0.5 μm with a MOCVD method in the same manner as in n-type GaN under-layer 103 except that Si was doped so that the carrier concentration became 5×10¹⁸/cm³.

Then, the temperature of sapphire substrate 101 was lowered to 700° C., nitrogen as carrier gas and ammonia, TMG, and TMI (trimethyl indium) as raw material gas flowed in the reaction furnace, and an In_{0.25}Ga_{0.75}N layer having a thickness of 2.5 nm and a GaN layer having a thickness of 18 nm was grown alternatively with a six-cycle MOCVD method, to form a light emitting layer 105 having a multiplex quantum well structure on n-type GaN contact layer 104. Moreover, it is needless to say that TMI was not flowed in the reaction furnace when the GaN layer was grown in the formation of light emitting layer 105.

Next, the temperature of sapphire substrate 101 was raised to 950° C. and hydrogen as carrier gas, ammonia, TMG, and TMA (trimethyl aluminum) as raw material gas, and CP2Mg (cyclopentadienyl magnesium) as impurity gas flowed in the reaction furnace, to grow a p-type AlGaN cladding layer 106 made of Al_{0.15}Ga_{0.85}N doped with Mg at a concentration of 1×10²⁰/cm³ on light emitting layer 105 to a thickness of about 30 nm with a MOCVD method.

The temperature of sapphire substrate 101 was kept to 950° C. and hydrogen as carrier gas, ammonia and TMG as raw material gas, and CP2Mg as impurity gas flowed in the reaction furnace, to grow a p-type GaN contact layer 107 made of GaN and doped with Mg at a concentration of 1×10²⁰/cm³ was p-type AlGaN cladding layer 106 to a thickness of 0.1 μm with a MOCVD method

After that, the temperature of sapphire substrate 101 was lowered to 750° C. and nitrogen gas as carrier gas, ammonia, TMG, and TMI as raw material gas, and CP2Mg as impurity gas flowed in the reaction furnace, to grow a p-type tunnel junction layer 108 made of In_{0.25}Ga_{0.75}N doped with Mg at a concentration of 1×10²⁰/cm³ on p-type GaN contact layer 107 to a thickness of 20 nm with a MOCVD method. Here, the band gap of p-type GaN contact layer 107 becomes larger than the band gap of p-type tunnel junction layer 108.

Further, the temperature of sapphire substrate 101 was kept to 750° C. and nitrogen as carrier gas, ammonia and TMG as raw material gas, and silane as impurity gas flowed in the reaction furnace, to grow an n-type tunnel junction layer 109 (concentration of n-type dopant: 1×10¹⁹/cm³) made of GaN doped with Si at a concentration of 1×10¹⁹/cm³ on p-type tunnel junction layer 108 to a thickness of 15 nm with a MOCVD method.

After that, the temperature of sapphire substrate 101 was raised to 950° C. and hydrogen as carrier gas, ammonia and TMG as raw material gas, and silane as impurity gas flowed in the reaction furnace, to grow an n-type GaN layer 111 made of GaN doped with Si at a concentration of 1×10¹⁹/cm³ on n-type tunnel junction layer 109 to a thickness of 0.2 μm with a MOCVD method.

Next, the temperature of sapphire substrate 101 was lowered to 700° C. and nitrogen as carrier gas flowed in the reaction furnace, to perform annealing.

Then, after the above-described annealing, the wafer was taken out from the reaction furnace, and a mask patterned in a prescribed shape was formed on the surface of n-type GaN layer 111 of the top layer of the wafer. A part of the above-described wafer was etched from the n-type GaN layer side with a RIE (Reactive Ion Etching) method) to expose a part of the surface of n-type GaN contact layer 104.

Then, a pad electrode 112 was formed on the surface of n-type GaN layer 111, and a pad electrode 113 was formed on the surface of n-type GaN contact layer 104. Here, pad electrode 112 and pad electrode 113 were formed at the same time by layering a Ti layer and an Al layer one by one on the surface of n-type GaN layer 111 and the surface of n-type GaN contact layer 104, respectively. After that, a nitride semiconductor light emitting diode device of Example 1 having a configuration shown in the schematic cross-sectional view of FIG. 2 was produced by dicing the wafer into a plurality of chips.

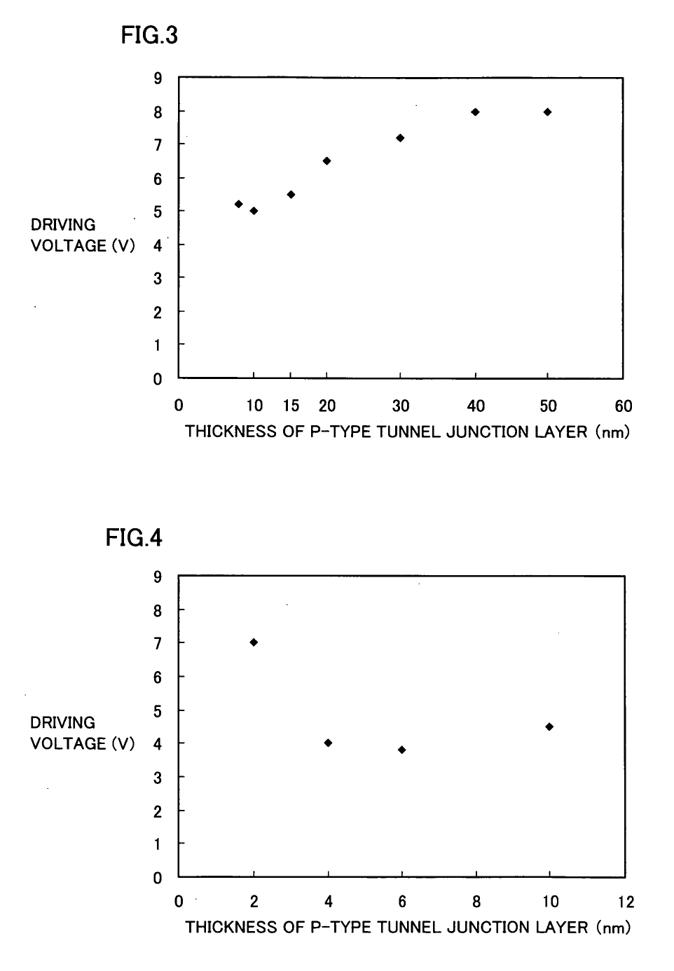

FIG. 3 shows a relationship between the thickness (nm) of p-type tunnel junction layer 108 and the driving voltage (V) of a nitride semiconductor light emitting diode device in Example 1. P-type tunnel junction layer 108 is equivalent to the In-containing layer in the nitride semiconductor light emitting diode device of Example 1. Further, the thickness of p-type tunnel junction layer 108 is equivalent to the shortest distance of an interface of p-type tunnel junction layer 108 and the layer (p-type GaN contact layer 107) with a larger band gap than it and an interface of p-type tunnel junction layer 108 and n-type tunnel junction layer 109 in the nitride semiconductor light emitting diode device of Example 1. Moreover, the driving voltage is one when the injection current is 20 mA.

As is obvious from FIG. 3, in the nitride semiconductor light emitting diode device of Example 1, in the case that the above-described shortest distance (thickness of n-type tunnel junction layer 108) is less than 40 nm, preferably 20 nm or less, and particularly 15 nm or less, it was confirmed that the driving voltage decreases drastically. Further, it was confirmed that the driving voltage tends to decrease as the above-described shortest distance (thickness of p-type tunnel junction layer 108) decrease in the nitride semiconductor light emitting diode device of Example 1.

### Example 2

In Example 2, the nitride semiconductor light emitting diode device with the configuration shown in the schematic cross-sectional view of FIG. 2 was manufactured.

P-type GaN contact layer 107 was grown with the same conditions and the same method as in Example 1.

After the growth of p-type GaN contact layer 107, the temperature of sapphire substrate 101 was lowered to 750° C. and nitrogen gas as carrier gas, ammonia, TMG, and TMI as raw material gas, and CP2Mg as impurity gas flowed in the reaction furnace, to grow p-type tunnel junction layer 108 (concentration of p-type dopant: 1×10²⁰/cm³) made of In_{0.1}Ga_{0.9}N doped with Mg at a concentration of 1×10²⁰/cm³ on p-type GaN contact layer 107 to a thickness of 10 nm with a MOCVD method. The band gap of p-type GaN contact layer 107 becomes larger than the band gap of p-type tunnel junction layer 108. Further, in the nitride semiconductor light emitting diode device in Example 2, the thickness of p-type tunnel junction layer 108 is equivalent to the shortest distance of an interface of p-type tunnel junction layer 108 and the layer (p-type GaN contact layer 107) with a larger band gap than it and an interface of p-type tunnel junction layer 108 and n-type tunnel junction layer 109.

Then, the nitride semiconductor light emitting diode device in Example 2 was produced with the same conditions and the same method as in Example 1.

It was confirmed that the driving voltage in the case that the injection current of the nitride semiconductor light emitting diode device of Example 2 is 20 mA becomes higher than that when the thickness of p-type tunnel junction layer 108 of the nitride semiconductor light emitting diode device in Example 1 is 10 nm.

### Example 3

In Example 3, the nitride semiconductor light emitting diode device with the configuration shown in the schematic cross-sectional view of FIG. 2 was manufactured.

P-type GaN contact layer 107 was grown with the same conditions and the same method as in Example 1.

Then, after the growth of p-type GaN contact layer 107, the temperature of sapphire substrate 101 was lowered to 650° C. and nitrogen gas as carrier gas, ammonia, TMG, and TMI as raw material gas, and CP2Mg as impurity gas flowed in the reaction furnace, to grow p-type tunnel junction layer 108 (concentration of p-type dopant: 1×10²⁰/cm³) made of In_{0.5}Ga_{0.5}N doped with Mg at a concentration of 1×10²⁰/cm³ on p-type GaN contact layer 107 to an arbitrary thickness in the range of 2 to 10 nm with a MOCVD method. The band gap of p-type GaN contact layer 107 becomes larger than the band gap of p-type tunnel junction layer 108.

Then, the nitride semiconductor light emitting diode device in Example 3 was produced with the same conditions and the same method as in Example 1.

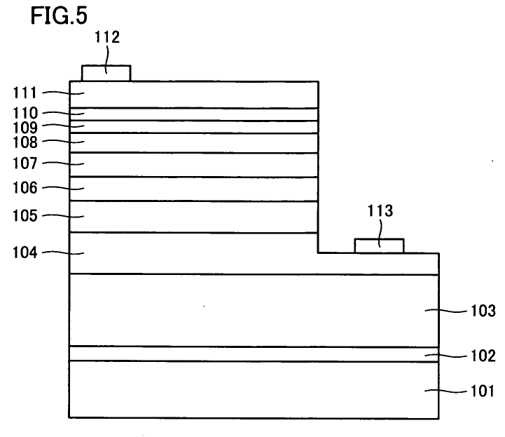

FIG. 4 shows a relationship between the thickness (nm) of p-type tunnel junction layer 108 and the driving voltage (V) of a nitride semiconductor light emitting diode device in Example 3. In the nitride semiconductor light emitting diode device in Example 3, p-type tunnel junction layer 108 is equivalent to the In-containing layer. Further, also in the nitride semiconductor light emitting diode device in Example 3, the thickness of p-type tunnel junction layer 108 is equivalent to the shortest distance of an interface of p-type tunnel junction layer 108 and the layer (p-type GaN contact layer 107) with a larger band gap than it and an interface of p-type tunnel junction layer 108 and n-type tunnel junction layer 109. Moreover, the driving voltage is one when the injection current is 20 mA.

As is obvious from FIG. 4, it was confirmed that the driving voltage decreases drastically in the nitride semiconductor light emitting diode device in Example 3 in the case that the above-described shortest distance (the thickness of p-type tunnel junction layer 108) is 10 nm or less, and preferably 4 nm to 6 nm. Further, the driving voltage became smallest in the nitride semiconductor light emitting diode device in Example 3 in the case that the above-described shortest distance (the thickness of p-type tunnel junction layer 108) was 6 nm.

Further, in the nitride semiconductor light emitting diode device in Example 3, the driving voltage when the above-described shortest distance (the thickness of p-type tunnel junction layer 108) was 2 nm became higher that when it was 6 nm. However, it was small as compared with the driving voltage when the above-described shortest distance (the thickness of p-type tunnel junction layer 108) was 40 nm or more.

### Example 4

In Example 4, the nitride semiconductor light emitting diode device with the configuration shown in the schematic cross-sectional view of FIG. 5 was manufactured.

P-type GaN contact layer 107 was grown with the same conditions and the same method as in Example 1.

After the growth of p-type GaN contact layer 107, the temperature of sapphire substrate 101 was lowered to 750° C. and nitrogen gas as carrier gas, ammonia, TMG, and TMI as raw material gas, and CP2Mg as impurity gas flowed in the reaction furnace, to grow p-type tunnel junction layer 108 (concentration of p-type dopant: 1×10²⁰/cm³) made of In_{0.25}Ga_{0.75}N doped with Mg at a concentration of 1×10²⁰/cm³ on p-type GaN contact layer 107 to a thickness of 5 nm with a MOCVD method. The band gap of p-type GaN contact layer 107 becomes larger than the band gap of p-type tunnel junction layer 108.

Then, the temperature of sapphire substrate 101 was kept to 750° C. and nitrogen as carrier gas, ammonia, TMI, and TMG as raw material gas, and silane as impurity gas flowed in the reaction furnace, to grow an n-type tunnel junction layer 109 (concentration of n-type dopant: 1×10¹⁹/cm³) made of In_{0.25}Ga_{0.75}N and doped with Si at a concentration of 1×10¹⁹/cm³ on p-type tunnel junction layer 108 to a thickness of 15 nm with a MOCVD method.

Next, the temperature of sapphire substrate 101 was kept to 750° C. and nitrogen as carrier gas, ammonia and TMG as raw material gas, and silane as impurity gas flowed in the reaction furnace, to grow an n-type GaN evaporation suppressing layer 110 made of GaN doped with Si at a concentration of 1×10¹⁹/cm³ on n-type tunnel junction layer 109 to a thickness of 15 nm with a MOCVD method. The band gap of n-type GaN evaporation suppressing layer 110 becomes larger than the band gap of n-type tunnel junction layer 109.

The temperature of sapphire substrate 101 was raised to 950° C. and hydrogen as carrier gas, ammonia and TMG as raw material gas, and silane as impurity gas flowed in the reaction furnace, to grow an n-type GaN layer 111 made of GaN doped with Si at a concentration of 1×10¹⁹/cm³ on n-type GaN evaporation suppressing layer 111 to a thickness of 0.2 μm with a MOCVD method.

After that, the nitride semiconductor light emitting diode device in Example 4 was produced with the same conditions and the same method as in Example 1.

It was confirmed that the driving voltage of the nitride semiconductor light emitting diode device in Example 4 is the same level as the driving voltage when the thickness of p-type tunnel junction layer 108 of the nitride semiconductor light emitting diode device in Example 1 is 10 nm.

Furthermore, it was confirmed that the driving voltage of the nitride semiconductor light emitting diode device produced by doping n-type tunnel junction layer 109 of the nitride semiconductor light emitting diode device in Example 4 with Si at a concentration of 5×10¹⁹/cm³ (concentration of n-type dopants: 5×10¹⁹/cm³) becomes larger than the driving voltage of the nitride semiconductor light emitting diode device in Example 4 produced by doping n-type tunnel junction layer 109 with Si at the concentration of 1×10¹⁹/cm³ (concentration of n-type dopants: 1×10¹⁹/cm³).

Moreover, the thickness of p-type tunnel junction layer 108 and the thickness of n-type tunnel junction layer 109 are equivalent to each other in the above-described shortest distance.

### Example 5

In Example 5, the nitride semiconductor light emitting diode device with the configuration shown in the schematic cross-sectional view of FIG. 5 was manufactured.

P-type GaN contact layer 107 was produced with the same conditions and the same method as in Example 1 until it was grown.

The temperature of sapphire substrate 101 was kept to 750° C. and nitrogen as carrier gas, ammonia, TMI, and TMG as raw material gas, and silane as impurity gas flowed in the reaction furnace, to grown an n-type tunnel junction layer 109 (concentration of n-type dopant: 1×10¹⁹/cm³) made of In_{0.25}Ga_{0.75}N doped with Si at a concentration of 1×10¹⁹/cm³ on p-type GaN contact layer 107 to a thickness of 10 nm with a MOCVD method. A part of the side of n-type tunnel junction layer 109 in contact with p-type GaN contact layer 107 functions as p-type tunnel junction layer 108.

Next, the temperature of sapphire substrate 101 was kept to 750° C. and nitrogen as carrier gas, ammonia and TMG as raw material gas, and silane as impurity gas flowed in the reaction furnace, to grow an n-type GaN evaporation suppressing layer 110 made of GaN doped with Si at a concentration of 1×10¹⁹/cm³ on n-type tunnel junction layer 109 to a thickness of 15 nm with a MOCVD method. The band gap of n-type GaN evaporation suppressing layer 110 becomes larger than the band gap of n-type tunnel junction layer 109.

After that, the temperature of sapphire substrate 101 was raised to 950° C. and hydrogen as carrier gas, ammonia and TMG as raw material gas, and silane as impurity gas flowed in the reaction furnace, to grow an n-type GaN layer 111 made of GaN doped with Si at a concentration of 1×10¹⁹/cm³ on n-type GaN evaporation suppressing layer 111 to a thickness of 0.2 μm with a MOCVD method.

Then, the nitride semiconductor light emitting diode device in Example 5 was produced with the same conditions and the same method as in Example 1.

It was confirmed that the driving voltage of the nitride semiconductor light emitting diode device in Example 5 is the same level as the driving voltage when the thickness of p-type tunnel junction layer 108 of the nitride semiconductor light emitting diode device in Example 1 is 10 nm.

Further, it was confirmed that the driving voltage of the nitride semiconductor light emitting diode device produced by undoping n-type GaN layer 111 of the nitride semiconductor light emitting diode device in Example 5 becomes the same level as the driving voltage of the nitride semiconductor light emitting diode device in Example 5 produced by doping n-type GaN layer 111 with Si at the concentration of 1×10¹⁹/cm³.

Furthermore, it was confirmed that the driving voltage of the nitride semiconductor light emitting diode device produced by doping n-type tunnel junction layer 109 of the nitride semiconductor light emitting diode device in Example 5 with Si at the concentration of 5×10¹⁹/cm³ (concentration of n-type dopants: 5×10¹⁹/cm³) becomes larger than the driving voltage of the nitride semiconductor light emitting diode device in Example 5 produced by doping n-type tunnel junction layer 109 with Si at the concentration of 1×10¹⁹/cm³.

Moreover, the thickness of n-type tunnel junction layer 109 is equivalent to the above-described shortest distance in the nitride semiconductor light emitting diode device in Example 5.

According to the present invention, the driving voltage of a nitride semiconductor light emitting device such as a nitride semiconductor light emitting diode device that has a tunnel junction and emits a blue light (for example, a wavelength of 430 nm to 490 nm) can be decreased.

Although the present invention is described and illustrated in detail, it is clearly understood that the same is by way of illustration and example only and is not to be taken by way of limitation, the scope of the present invention being interpreted by the terms of the appended claims.

What is claimed is:

1. A nitride semiconductor light emitting device comprising:
a substrate;
a first n-type nitride semiconductor layer;
a light emitting layer;
a p-type nitride semiconductor layer;
a p-type nitride semiconductor tunnel junction layer;
an n-type nitride semiconductor tunnel junction layer;
and a second n-type semiconductor layer;
formed on the substrate;
wherein said p-type nitride semiconductor tunnel junction layer and said n-type nitride semiconductor tunnel junction layer form a tunnel junction,
at least one of said p-type nitride semiconductor tunnel junction layer and said n-type nitride semiconductor tunnel junction layer contains In,
at least one of In-containing layers, which are at least one of said p-type nitride semiconductor tunnel junction layer and said n-type nitride semiconductor tunnel junction layer contacts with a layer having a larger band gap than the In-containing layer, and
at least one of shortest distances between an interface of said In-containing layer and said layer having a larger band gap and an interface of said p-type nitride semiconductor tunnel junction layer and said n-type nitride semiconductor tunnel junction layer is less than 40 nm.

2. The nitride semiconductor light emitting device according to claim 1, wherein the ratio of the number of In atoms to the total number of Al, Ga, and In atoms in said In-containing layer is larger than 0.1.

3. The nitride semiconductor light emitting device according to claim 1, wherein said n-type nitride semiconductor tunnel junction layer is an In-containing layer and the concentration of an n-type dopant in said n-type nitride semiconductor tunnel junction layer is less than 5×10¹⁹/cm³.

4. The nitride semiconductor light emitting device according to claim 3, wherein said n-type dopant is at least one kind selected from the group consisting of Si, Ge, and O.

5. The nitride semiconductor light emitting device according to claim 1, wherein the concentration of a p-type dopant in said p-type nitride semiconductor tunnel junction layer is 2×10¹⁹/cm³ or more.
